(19) United States
(12) Patent Application Publication
(10) Pub. No.: US 2026/0130169 A1
(43) Pub. Date: May 7, 2026

(54) CHIP TRANSFERRING SYSTEM, PROTECTION COVER AND CHIP TRANSFERRING METHOD

(71) Applicant: Taiwan Semiconductor Manufacturing Company, Ltd., Hsinchu (TW)

(72) Inventors: Yi-Chen Li, Taichung City (TW); Jen-Yuan Chang, Hsinchu City (TW)

(73) Assignee: Taiwan Semiconductor Manufacturing Company, Ltd., Hsinchu (TW)

(21) Appl. No.: 18/936,999

(22) Filed: Nov. 4, 2024

(51) Int. Cl. H01L 21/677

(52) U.S. Cl. CPC H10P 72/3308; H10P 72/3302

(57) ABSTRACT

A chip transferring system including a stage, a protection cover and a pick-and-place component is provided. The stage has a supporting region and is configured to support a workpiece by the supporting region. The protection cover includes a cover body configured to be located above the supporting region to cover the supporting region, wherein the cover body has an opening. The pick-and-place component is configured to pass through the opening of the cover body to pick a chip from the workpiece on the supporting region or place the chip to the workpiece on the supporting region. In addition, a protection cover and a chip transferring method are also provided.

### BACKGROUND

In recent years, the semiconductor industry has experienced rapid growth due to continuous improvement in integration density of various electronic components, e.g., transistors, diodes, resistors, capacitors, etc. For the most part, this improvement in integration density has come from successive reductions in minimum feature size, which allows more components to be integrated into a given area.

These smaller electronic components also require smaller packages that occupy less area than previous packages. Examples of the type of packages for semiconductors include quad flat packages (QFP), pin grid array (PGA) packages, ball grid array (BGA) packages, flip chips (FC) packages, three-dimensional integrated circuits (3DICs), wafer level packages (WLPs), package on package (PoP) devices and wafer on wafer (WoW) devices. There are many challenges related to transferring chips between workpieces (such as a wafer, a frame with a tape therein for carrying chips, a chip storage box, etc.). One challenge is particles on the workpiece. Specifically, in a restructure wafer step in the SoIC (System on Integrated Circuit) chip fabrication process, ion fan blows to the workpiece for avoiding ESD (electrostatic discharge). It was found that the overall chamber particle count was higher than that of ordinary machines. The reason is that the ion fan blows dust onto the workpiece. Therefore, during the chip transferring process, particles on chip will cause the tip of the pick-and-place component to stick with the particles which cause wear. No matter at which step the particle falls, it may affect the surface of the chip and bulge defect will be formed after bonding.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1A and FIG. 1B illustrate steps of transferring a chip by a chip transferring system in accordance with some embodiments.

FIG. 2 is a flow chart illustrating a chip transferring method corresponding to the chip transferring system of FIG. 1A and FIG. 1B.

FIG. 3 illustrates a partial step of transferring a chip by a chip transferring system in accordance with some embodiments.

FIG. 4 illustrates a partial step of transferring a chip by a chip transferring system in accordance with some embodiments.

FIG. 5 illustrates a partial step of transferring a chip by a chip transferring system in accordance with some embodiments.

FIG. 6 illustrates a partial step of transferring a chip by a chip transferring system in accordance with some embodiments.

FIG. 7A and FIG. 7B illustrate partial steps of transferring a chip by a chip transferring system in accordance with some embodiments.

FIG. 8A and FIG. 8B illustrate partial steps of transferring a chip by a chip transferring system in accordance with some embodiments.

FIG. 9A and FIG. 9B illustrate steps of transferring a chip by a chip transferring system in accordance with some embodiments.

FIG. 10A and FIG. 10B illustrate steps of transferring a chip by a chip transferring system in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

In embodiments of the present invention, protection covers configured to prevent dust or other types of particles from falling directly on a workpiece during the chip transferring process are discussed. The protection covers with or without movable plates for adjusting openings formed on the protection covers may facilitate the chip transferring process. Furthermore, non-fan ionizers may be attached on the inner surface of the protection covers for preventing dust or other types of particles from being blown onto the workpiece. Accordingly, the protection covers may prevent bulge defect due to particles.

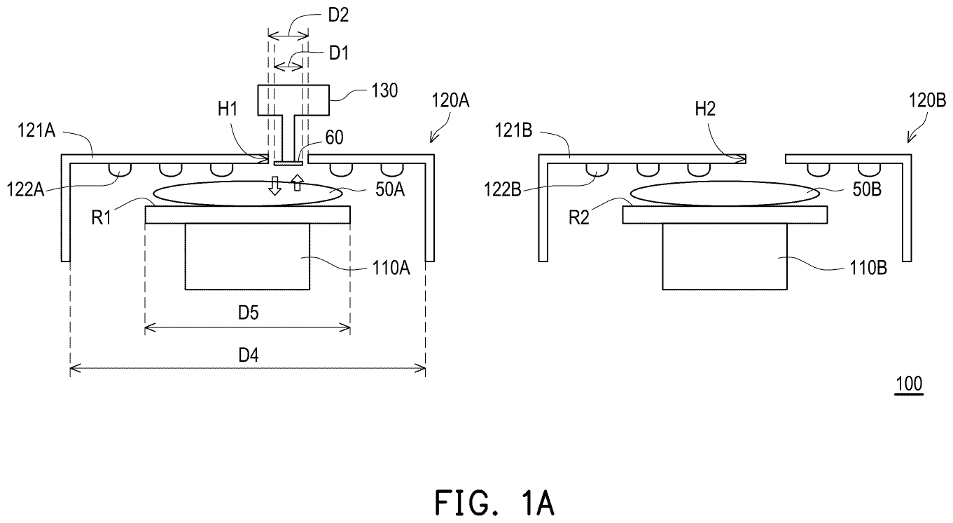

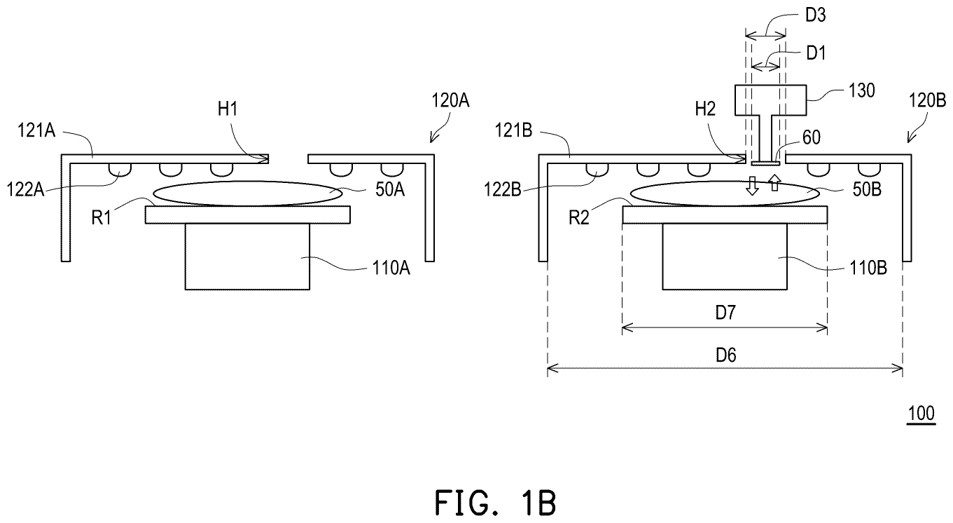

FIG. 1A and FIG. 1B illustrate steps of transferring a chip by a chip transferring system in accordance with some embodiments. Referring to FIG. 1A and FIG. 1B, the chip transferring system 100 includes a stage 110A, a stage 110B, a protection cover 120A, a protection cover 120B and a pick-and-place component 130. The stage 110A has a supporting region R1 and is configured to support a workpiece 50A by the supporting region R1. Similarly, the stage 110B has a supporting region R2 and is configured to support a workpiece 50B by the supporting region R2. The protection cover 120A includes a cover body 121A configured to be located above the supporting region R1 to cover the supporting region R1 and the workpiece 50A, and the cover body 121A of the protection cover 120A has an opening H1 located above the stage 110A. Similarly, the protection cover 120B includes a cover body 121B configured to be located above the supporting region R2 to cover the supporting region R2 and the workpiece 50B, and the cover body 121B of the protection cover 120B has an opening H2 located above the stage 110B.

The pick-and-place component 130 is configured to pass through the opening H1 of the cover body 121A to pick a chip 60 from the workpiece 50A on the supporting region R1 of the stage 110A, as shown in FIG. 1A. In addition, the pick-and-place component 130 is configured to pass through the opening H2 of the cover body 121B to place the chip 60 to the workpiece 50B on the supporting region R2 of the stage 110B, as shown in FIG. 1B. The workpiece 50A is a wafer, a frame with a tape therein for carrying chips, a chip storage box or other kinds of workpiece, and it is not limited thereto. Similarly, the workpiece 50B is a wafer, a frame with a tape therein for carrying chips, a chip storage box or other kinds of workpiece, and it is not limited thereto. That is, in the chip transferring process of the embodiments, the chip 60 may be transferred from a wafer to a frame, from a frame to another frame, from a frame to a wafer, or from a wafer to a chip storage box, etc. In addition, the pick-and-place component 130 may be driven by a robot arm or other types of automated drive devices and it is not limited thereto.

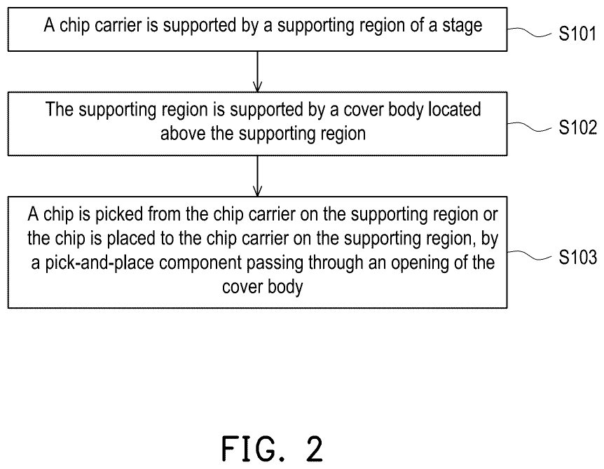

FIG. 2 is a flow chart illustrating a chip transferring method corresponding to the chip transferring system of FIG. 1A and FIG. 1B. Referring to FIG. 1A to FIG. 2, in the chip transferring process, the workpiece 50A is supported by the supporting region R1 of the stage 110A, and the workpiece 50B is supported by the supporting region R2 of the stage 110B, which is corresponding to the step S101 in FIG. 2. The supporting region R1 of the stage 110A is covered by the cover body 121A of the protection cover 120A located above the supporting region R1 of the stage 110A, and the supporting region R2 of the stage 110B is covered by the cover body 121B of the protection cover 120B located above the supporting region R2 of the stage 110B, which is corresponding to the step S102 in FIG. 2. The chip 60 is picked from the workpiece 50A on the supporting region R1 of the stage 110A by the pick-and-place component 130 passing through the opening H1 of the cover body 121A of the protection cover 120A as shown in FIG. 1A, and then the chip 60 is placed to the workpiece 50B on the supporting region R2 of the stage 110B by the pick-and-place component 130 passing through the opening H2 of the cover body 121B of the protection cover 120B as shown in FIG. 1B, which is corresponding to the step S103 in FIG. 2.

Under the above-mentioned configuration, the cover body 121A prevents dust or other types of particles from falling directly on the workpiece 50A and the cover body 121B prevents particles from falling directly on the workpiece 50B during the chip transferring process.

In some embodiments, the protection cover 120A further includes a plurality of ionizers 122A, and each of the ionizers 122A of the protection cover 120A is disposed on the cover body 121A of the protection cover 120A and is configured to provide ions towards the supporting region R1 of the stage 110A and the workpiece 50A on the supporting region R1 of the stage 110A. Similarly, the protection cover 120B further includes a plurality of ionizers 122B, and each of the ionizers 122B of the protection cover 120B is disposed on the cover body 121B of the protection cover 120B and is configured to provide ions towards the supporting region R2 of the stage 110B and the workpiece 50B on the supporting region R2 of the stage 110B. Specifically, each of the ionizers 122A of the protection cover 120A is, for example, a non-fan ionizer. Similarly, each of the ionizers 122B of the protection cover 120B is, for example, a non-fan ionizer. Therefore, an effect of preventing dust or other types of particles from being blown onto the workpiece by ion fans is achieved.

As shown in FIG. 1A, a width D2 of the opening H1 of the cover body 121A of the protection cover 120A is, for example, greater than a width D1 of the chip 60, such that the chip 60 may be pass through the opening H1 of the cover body 121A of the protection cover 120A successfully. Similarly, as shown in FIG. 1B, a width D3 of the opening H2 of the cover body 121B of the protection cover 120B is, for example, greater than the width D1 of the chip 60, such that the chip 60 may be pass through the opening H2 of the cover body 121B of the protection cover 120B successfully. Further, the width D2 of the opening H1 of the cover body 121A of the protection cover 120A is, for example, equal to the width D1 of the chip 60 plus 4 mm, so as to preventing the width D2 of the opening H1 of the cover body 121A of the protection cover 120A being too large. Similarly, the width D3 of the opening H2 of the cover body 121B of the protection cover 120B is, for example, equal to the width D1 of the chip 60 plus 4 mm, so as to preventing the width D3 of the opening H2 of the cover body 121B of the protection cover 120B being too large.

In some embodiments, the stage 110A is configured to move relatively to the cover body 121A of the protection cover 120A for moving the workpiece 50A on the cover body 121A of the protection cover 120A relatively to the opening H1 of the cover body 121A of the protection cover 120A, such that the pick-and-place component 130 may pick chips from different locations on the workpiece 50A on the supporting region R1 of the stage 110A by passing through the opening H1 of the cover body 121A of the protection cover 120A. The stage 110A may be driven to move horizontally and/or perpendicularly by any types of automated drive devices and it is not limited thereto. Similarly, the stage 110B is configured to move relatively to the cover body 121B of the protection cover 120B for moving the workpiece 50B on the cover body 121B of the protection cover 120B relatively to the opening H2 of the cover body 121B of the protection cover 120B, such that the pick-and-place component 130 may place chips to different locations on the workpiece 50B on the supporting region R2 of the stage 110B by passing through the opening H2 of the cover body 121B of the protection cover 120B. The stage 110B may be driven to move horizontally and/or perpendicularly by any types of automated drive devices and it is not limited thereto.

As shown in FIG. 1A, a width D4 of the cover body 121A of the protection cover 120A is greater than a width D5 of the stage 110A, so as to provide enough space for the stage 110A to move relatively to the cover body 121A of the protection cover 120A and avoid the stage 110A from hitting the cover body 121A of the protection cover 120A. Similarly, as shown in FIG. 1B, a width D6 of the cover body 121B of the protection cover 120B is greater than a width D7 of the stage 110B, so as to provide enough space for the stage 110B to move relatively to the cover body 121B of the protection cover 120B and avoid the stage 110B from hitting the cover body 121B of the protection cover 120B.

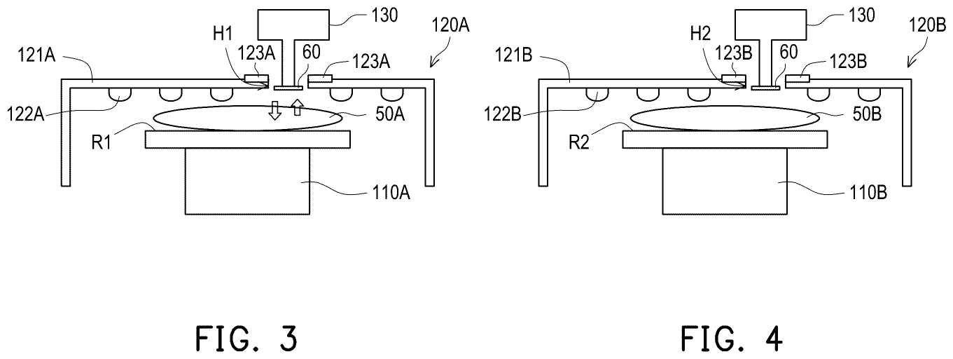

FIG. 3 illustrates a partial step of transferring a chip by a chip transferring system in accordance with some embodiments. Referring to FIG. 3, in some embodiments, the protection cover 120A further includes at least one movable plate 123A (two movable plates 123A are illustrated). The movable plates 123A of the protection cover 120A are disposed on the cover body 121A of the protection cover 120A and are configured to move along the cover body 121A of the protection cover 120A to at least partially cover the opening H1 of the cover body 121A of the protection cover 120A Thus, the width of the opening H1 of the cover body 121A of the protection cover 120A can be adjusted by the positions of the movable plates 123A, so as to reduce the width of the opening H1 of the cover body 121A of the protection cover 120A as much as possible while allowing the chip 60 to pass through the opening H1 of the cover body 121A of the protection cover 120A. The movable plates 123A may be driven to move horizontally by any types of automated drive devices and it is not limited thereto.

FIG. 4 illustrates a partial step of transferring a chip by a chip transferring system in accordance with some embodiments. Referring to FIG. 4, in some embodiments, the protection cover 120B further includes at least one movable plate 123B (two movable plates 123B are illustrated). The movable plates 123B of the protection cover 120B are disposed on the cover body 121B of the protection cover 120B and are configured to move along the cover body 121B of the protection cover 120B to at least partially cover the opening H2 of the cover body 121B of the protection cover 120B. Thus, the width of the opening H2 of the cover body 121B of the protection cover 120B can be adjusted by the positions of the movable plates 123B, so as to reduce the width of the opening H2 of the cover body 121B of the protection cover 120B as much as possible while allowing the chip 60 to pass through the opening H2 of the cover body 121B of the protection cover 120B. The movable plates 123B may be driven to move horizontally by any types of automated drive devices and it is not limited thereto.

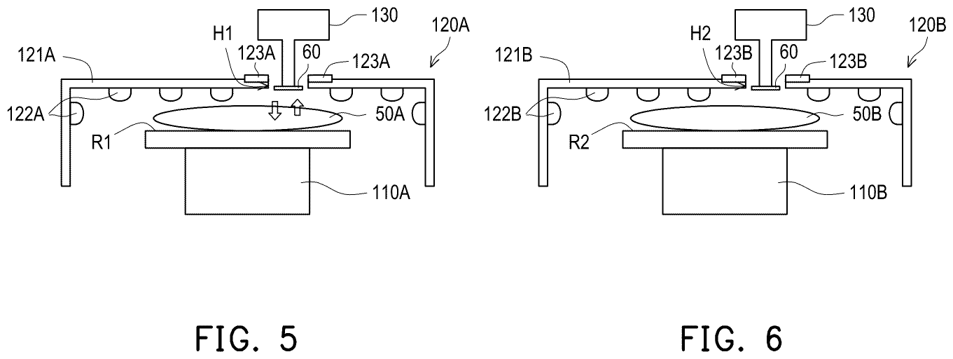

FIG. 5 illustrates a partial step of transferring a chip by a chip transferring system in accordance with some embodiments. The configuration illustrated in FIG. 5 is different from the configuration illustrated in FIG. 3 in that, the number of the ionizers 122A of the protection cover 120A in FIG. 5 is more than the number of the ionizers 122A of the protection cover 120A in FIG. 3. Specifically, in the embodiment of FIG. 5, some of the ionizers 122A of the protection cover 120A are disposed on side walls of the cover body 121A of the protection cover 120A. In other embodiments, the ionizers 122A of the protection cover 120A may be disposed on any suitable positions of the cover body 121A of the protection cover 120A and it is not limited thereto.

FIG. 6 illustrates a partial step of transferring a chip by a chip transferring system in accordance with some embodiments. The configuration illustrated in FIG. 6 is different from the configuration illustrated in FIG. 4 in that, the number of the ionizers 122B of the protection cover 120B in FIG. 6 is more than the number of the ionizers 122B of the protection cover 120B in FIG. 4. Specifically, in the embodiment of FIG. 6, some of the ionizers 122B of the protection cover 120B are disposed on side walls of the cover body 121B of the protection cover 120B. In other embodiments, the ionizers 122B of the protection cover 120B may be disposed on any suitable positions of the cover body 121B of the protection cover 120B and it is not limited thereto.

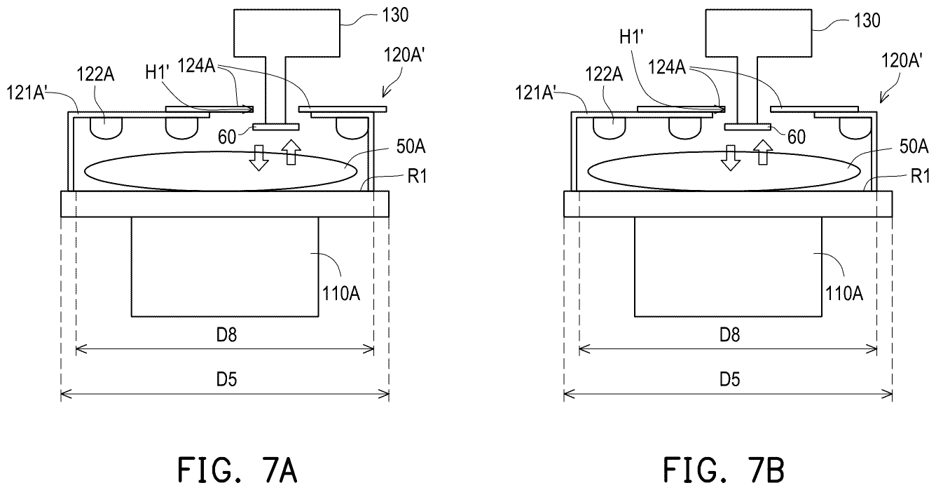

FIG. 7A and FIG. 7B illustrate partial steps of transferring a chip by a chip transferring system in accordance with some embodiments. The configuration illustrated in FIG. 7A and FIG. 7B is different from the configuration illustrated in FIG. 3 in that, the size of the cover body 121A′ of the protection cover 120A′ illustrated in FIG. 7A and FIG. 7B is smaller than the size of the cover body 121A of the protection cover 120A illustrated in FIG. 3. Specifically, a width D8 of the cover body 121A′ of the protection cover 120A′ is less than the width D5 of the stage 110A. In addition, the cover body 121A′ of the protection cover 120A′ is configured to be placed on the stage 110A.

Further, in the embodiment of FIG. 7A and FIG. 7B, the protection cover 120A′ further includes at least one movable plate 124A (two movable plates 124A are illustrated) instead of the movable plates 123A of the protection cover 120A in FIG. 3. The movable plates 124A are disposed on the cover body 121A′ of the protection cover 120A′ and are configured to move along the cover body 121A′ of the protection cover 120A′ to formed an opening H1′ at different positions on the cover body 121A′ of the protection cover 120A′, as shown in FIG. 7A and FIG. 7B respectively. Therefore, the pick-and-place component 130 may pick chips from different locations on the workpiece 50A on the supporting region R1 of the stage 110A by passing through the opening H1′ of the cover body 121A′ of the protection cover 120A′. The movable plates 124A of the protection cover 120A′ may be driven to move horizontally by any types of automated drive devices and it is not limited thereto.

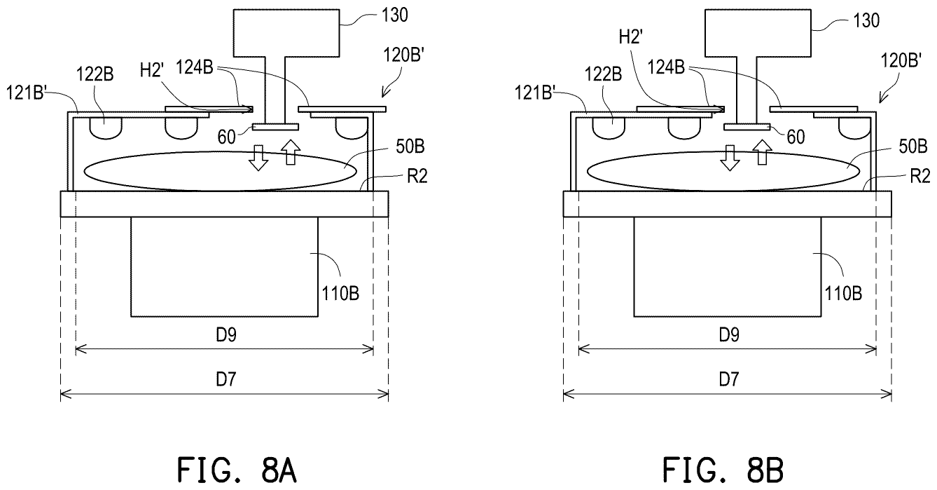

FIG. 8A and FIG. 8B illustrate partial steps of transferring a chip by a chip transferring system in accordance with some embodiments. The configuration illustrated in FIG. 8A and FIG. 8B is different from the configuration illustrated in FIG. 4 in that, the size of the cover body 121B′ of the protection cover 120B′ illustrated in FIG. 8A and FIG. 8B is smaller than the size of the cover body 121B of the protection cover 120B illustrated in FIG. 4. Specifically, a width D9 of the cover body 121B′ of the protection cover 120B′ is less than the width D7 of the stage 110B. In addition, the cover body 121B′ of the protection cover 120B′ is configured to be placed on the stage 110B.

Further, in the embodiment of FIG. 8A and FIG. 8B, the protection cover 120B′ further includes at least one movable plate 124B (two movable plates 124B are illustrated) instead of the movable plates 123B of the protection cover 120B in FIG. 4. The movable plates 124B are disposed on the cover body 121B′ of the protection cover 120B′ and are configured to move along the cover body 121B′ of the protection cover 120B′ to formed an opening H2′ at different positions on the cover body 121B′ of the protection cover 120B′, as shown in FIG. 8A and FIG. 8B respectively. Therefore, the pick-and-place component 130 may pick chips from different locations on the workpiece 50B on the supporting region R2 of the stage 110B by passing through the opening H2′ of the cover body 121B′ of the protection cover 120B′. The movable plates 124B of the protection cover 120B′ may be driven to move horizontally by any types of automated drive devices and it is not limited thereto.

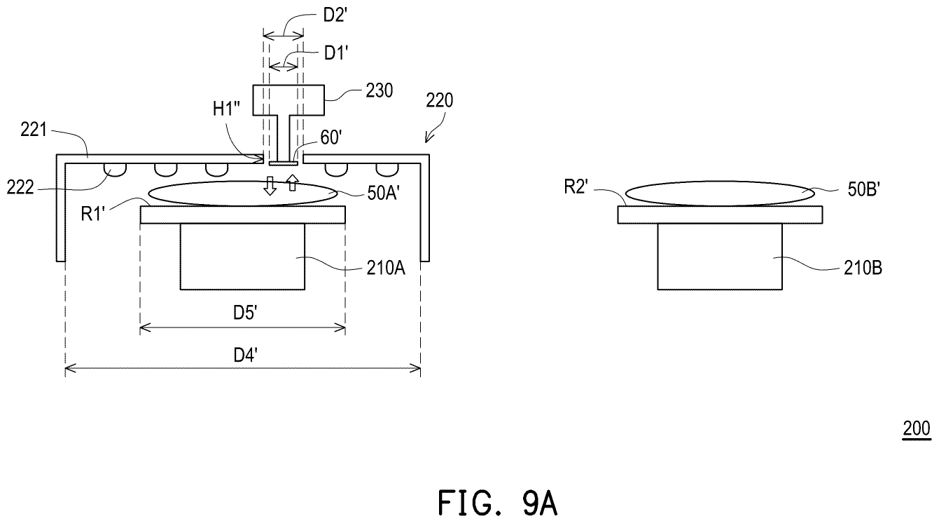

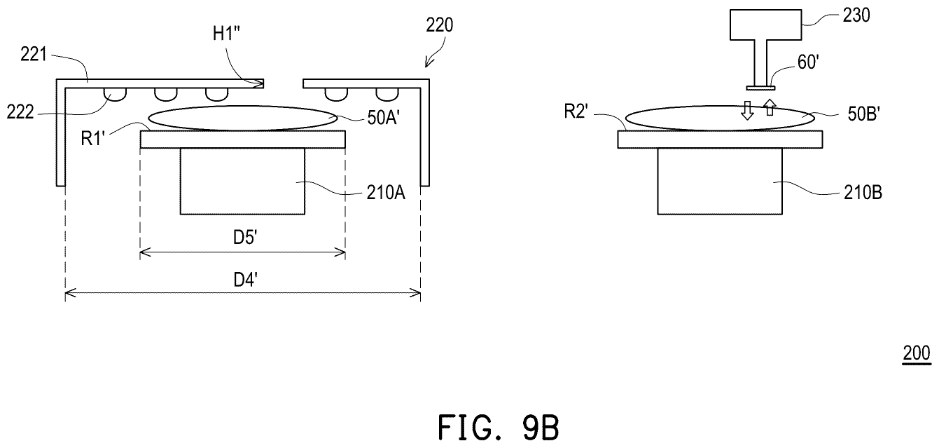

FIG. 9A and FIG. 9B illustrate steps of transferring a chip by a chip transferring system in accordance with some embodiments. The embodiment illustrated in FIG. 9A and FIG. 9B is different from the embodiment illustrated in FIG. 1A and FIG. 1B in that, the protection cover 120B shown in FIG. 1A and FIG. 1B is omitted in FIG. 9A and FIG. 9B. Specifically, referring to FIG. 9A and FIG. 9B, the chip transferring system 200 includes a stage 210A, a stage 210B, a protection cover 220 and a pick-and-place component 230. The stage 210A has a supporting region R1′ and is configured to support a workpiece 50A′ by the supporting region R1′. Similarly, the stage 210B has a supporting region R2′ and is configured to support a workpiece 50B′ by the supporting region R2′. The protection cover 220 includes a cover body 221 configured to be located above the supporting region R1′ to cover the supporting region R1′ and the workpiece 50A′, and the cover body 221 of the protection cover 220 has an opening H1″.

The pick-and-place component 230 is configured to pass through the opening H1″ of the cover body 221 to pick a chip 60′ from the workpiece 50A′ on the supporting region R1′ of the stage 210A, as shown in FIG. 9A. In addition, the pick-and-place component 230 is configured to place the chip 60′ to the workpiece 50B′ on the supporting region R2′ of the stage 210B, as shown in FIG. 9B. The workpiece 50A′ is a wafer, a frame with a tape therein for carrying chips, a chip storage box or other kinds of workpiece, and it is not limited thereto. Similarly, the workpiece 50B′ is a wafer, a frame with a tape therein for carrying chips, a chip storage box or other kinds of workpiece, and it is not limited thereto. That is, in the chip transferring process of the embodiments, the chip 60′ may be transferred from a wafer to a frame, from a frame to another frame, from a frame to a wafer, or from a wafer to a chip storage box, etc. In addition, the pick-and-place component 230 may be driven by a robot arm or other types of automated drive devices and it is not limited thereto.

In the chip transferring process, the workpiece 50A′ is supported by the supporting region R1′ of the stage 210A, and the workpiece 50B′ is supported by the supporting region R2′ of the stage 210B. The supporting region R1′ of the stage 210A is covered by the cover body 221 of the protection cover 220 located above the supporting region R1′ of the stage 210A. Thereafter, the chip 60′ is picked from the workpiece 50A′ on the supporting region R1′ of the stage 210A by the pick-and-place component 230 passing through the opening H1″ of the cover body 221 of the protection cover 220 as shown in FIG. 9A, and then the chip 60′ is placed to the workpiece 50B′ on the supporting region R2′ of the stage 210B by the pick-and-place component 230 as shown in FIG. 9B.

Under the above-mentioned configuration, the cover body 221 prevents dust or other types of particles from falling directly on the workpiece 50A′ during the chip transferring process.

In some embodiments, the protection cover 220 further includes a plurality of ionizers 222, and each of the ionizers 222 of the protection cover 220 is disposed on the cover body 221 of the protection cover 220 and is configured to provide ions towards the supporting region R1′ of the stage 210A and the workpiece 50A′ on the supporting region R1′ of the stage 210A. Specifically, each of the ionizers 222 of the protection cover 220 is, for example, a non-fan ionizer. Therefore, an effect of preventing dust or other types of particles from being blown onto the workpiece by ion fans is achieved.

As shown in FIG. 9A, a width D2′ of the opening H1″ of the cover body 221 of the protection cover 220 is, for example, greater than a width D1′ of the chip 60′, such that the chip 60′ may be pass through the opening H1″ of the cover body 221 of the protection cover 220 successfully. Further, the width D2′ of the opening H1″ of the cover body 221 of the protection cover 220 is, for example, equal to the width D1′ of the chip 60′ plus 4 mm, so as to preventing the width D2′ of the opening H1″ of the cover body 221 of the protection cover 220 being too large.

In some embodiments, the stage 210A is configured to move relatively to the cover body 221 of the protection cover 220 for moving the workpiece 50A′ on the cover body 221 of the protection cover 220 relatively to the opening H1″ of the cover body 221 of the protection cover 220, such that the pick-and-place component 230 may pick chips from different locations on the workpiece 50A′ on the supporting region R1′ of the stage 210A by passing through the opening H1″ of the cover body 221 of the protection cover 220. The stage 210A may be driven to move horizontally and/or perpendicularly by any types of automated drive devices and it is not limited thereto.

As shown in FIG. 9A, a width D4′ of the cover body 221 of the protection cover 220 is greater than a width D5′ of the stage 210A, so as to provide enough space for the stage 210A to move relatively to the cover body 221 of the protection cover 220 and avoid the stage 210A from hitting the cover body 221 of the protection cover 220.

The configurations of the embodiments illustrated in FIG. 3, FIG. 5, FIG. 7A and FIG. 7B may be applied to the embodiment of FIG. 9A and FIG. 9B, and the details are not repeated here.

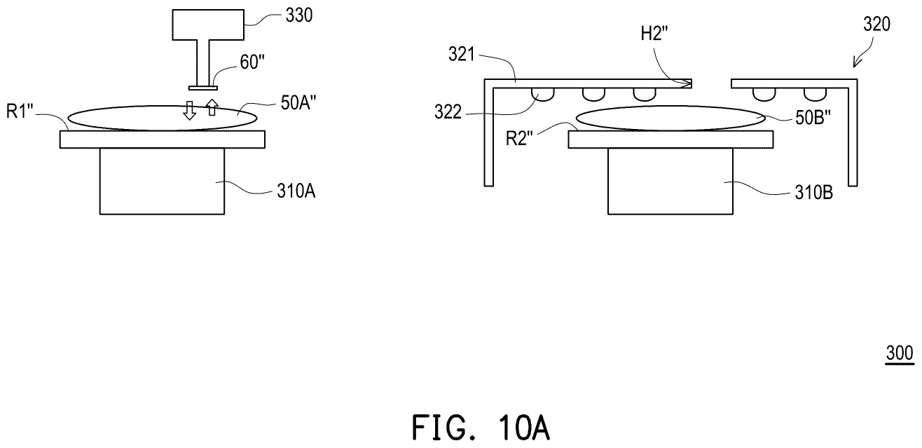

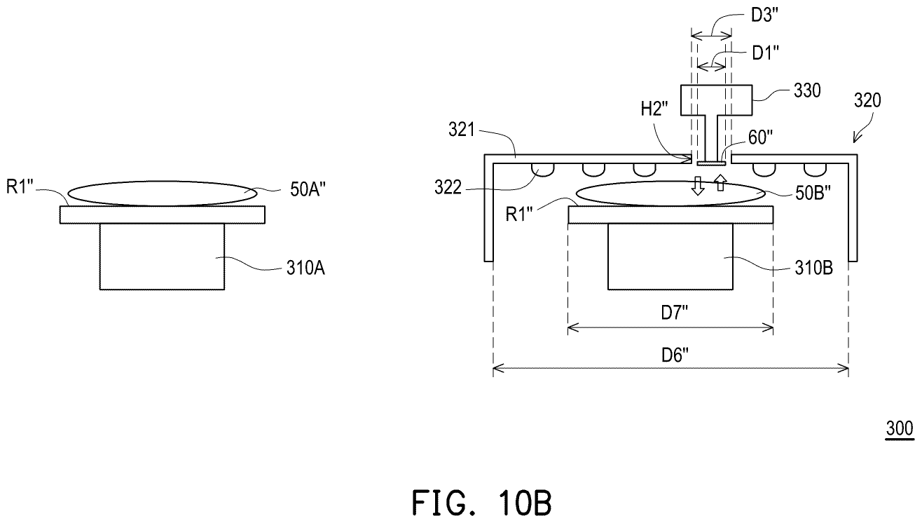

FIG. 10A and FIG. 10B illustrate steps of transferring a chip by a chip transferring system in accordance with some embodiments. The embodiment illustrated in FIG. 10A and FIG. 10B is different from the embodiment illustrated in FIG. 1A and FIG. 1B in that, the protection cover 120A shown in FIG. 1A and FIG. 1B is omitted in FIG. 10A and FIG. 10B. Specifically, referring to FIG. 10A and FIG. 10B, the chip transferring system 300 includes a stage 310A, a stage 310B a protection cover 320 and a pick-and-place component 330. The stage 310A has a supporting region R1″ and is configured to support a workpiece 50A″ by the supporting region R1″. Similarly, the stage 310B has a supporting region R2″ and is configured to support a workpiece 50B″ by the supporting region R2″. The protection cover 320 includes a cover body 321 configured to be located above the supporting region R2″ to cover the supporting region R2″ and the workpiece 50B″, and the cover body 321 of the protection cover 320 has an opening H2″.

The pick-and-place component 330 is configured to pick a chip 60″ from the workpiece 50A″ on the supporting region R1″ of the stage 310A, as shown in FIG. 10A. In addition, the pick-and-place component 330 is configured to pass through the opening H2″ of the cover body 321 to place the chip 60″ to the workpiece 50B″ on the supporting region R2″ of the stage 310B, as shown in FIG. 10B. The workpiece 50A″ is a wafer, a frame with a tape therein for carrying chips, a chip storage box or other kinds of workpiece, and it is not limited thereto. Similarly, the workpiece 50B″ is a wafer, a frame with a tape therein for carrying chips, a chip storage box or other kinds of workpiece, and it is not limited thereto. That is, in the chip transferring process of the embodiments, the chip 60″ may be transferred from a wafer to a frame, from a frame to another frame, from a frame to a wafer, or from a wafer to a chip storage box, etc. In addition, the pick-and-place component 330 may be driven by a robot arm or other types of automated drive devices and it is not limited thereto.

In the chip transferring process, the workpiece 50A″ is supported by the supporting region R1″ of the stage 310A, and the workpiece 50B″ is supported by the supporting region R2″ of the stage 310B. The supporting region R2″ of the stage 310B is covered by the cover body 321 of the protection cover 320 located above the supporting region R2″ of the stage 310B. Thereafter, the chip 60″ is picked from the workpiece 50A″ on the supporting region R1″ of the stage 310A by the pick-and-place component 330 as shown in FIG. 10A, and then the chip 60″ is placed to the workpiece 50B″ on the supporting region R2″ of the stage 310B by the pick-and-place component 330 passing through the opening H2″ of the cover body 321 of the protection cover 320 as shown in FIG. 10B.

Under the above-mentioned configuration, the cover body 321 prevents dust or other types of particles from falling directly on the workpiece 50B″ during the chip transferring process.

In some embodiments, the protection cover 320 further includes a plurality of ionizers 322, and each of the ionizers 322 of the protection cover 320 is disposed on the cover body 321 of the protection cover 320 and is configured to provide ions towards the supporting region R2″ of the stage 310B and the workpiece 50B″ on the supporting region R2″ of the stage 310B. Specifically, each of the ionizers 322 of the protection cover 320 is, for example, a non-fan ionizer. Therefore, an effect of preventing dust or other types of particles from being blown onto the workpiece by ion fans is achieved.

As shown in FIG. 10B, a width D3″ of the opening H2″ of the cover body 321 of the protection cover 320 is, for example, greater than a width D1″ of the chip 60″, such that the chip 60″ may be pass through the opening H2″ of the cover body 321 of the protection cover 320 successfully. Further, the width D3″ of the opening H2″ of the cover body 321 of the protection cover 320 is, for example, equal to the width D1″ of the chip 60″ plus 4 mm, so as to preventing the width D3″ of the opening H2″ of the cover body 321 of the protection cover 320 being too large.

In some embodiments, the stage 310B is configured to move relatively to the cover body 321 of the protection cover 320 for moving the workpiece 50B″ on the cover body 321 of the protection cover 320 relatively to the opening H2″ of the cover body 321 of the protection cover 320, such that the pick-and-place component 330 may place chips to different locations on the workpiece 50B″ on the supporting region R2″ of the stage 310B by passing through the opening H2″ of the cover body 321 of the protection cover 320. The stage 310B may be driven to move horizontally and/or perpendicularly by any types of automated drive devices and it is not limited thereto.

As shown in FIG. 10B, a width D6″ of the cover body 321 of the protection cover 320 is greater than a width D7″ of the stage 310B, so as to provide enough space for the stage 310B to move relatively to the cover body 321 of the protection cover 320 and avoid the stage 310B from hitting the cover body 321 of the protection cover 320.

The configurations of the embodiments illustrated in FIG. 4, FIG. 6, FIG. 8A and FIG. 8B may be applied to the embodiment of FIG. 10A and FIG. 10B, and the details are not repeated here.

In summary, based on the configurations and operations of the chip transferring system, the protection cover and the chip transferring method in the embodiments, the cover body prevents dust or other types of particles from falling directly on the workpiece. Therefore, during the chip transferring process, the tip of the pick-and-place component is prevented from sticking with particles which cause wear, and bulge defect due to particles is avoided after bonding.

In accordance with some embodiments, a chip transferring system includes a stage, a protection cover and a pick-and-place component. The stage has a supporting region and is configured to support a workpiece by the supporting region. The protection cover includes a cover body configured to be located above the supporting region to cover the supporting region, wherein the cover body has an opening. The pick-and-place component is configured to pass through the opening of the cover body to pick a chip from the workpiece on the supporting region or place the chip to the workpiece on the supporting region.

In accordance with some embodiments, a protection cover is adapted to a chip transferring system, the chip transferring system includes a stage, the stage has a supporting region for supporting a workpiece, and the protection cover includes a cover body and at least one ionizer. The cover body is configured to be located above the supporting region to cover the supporting region. The at least one ionizer is disposed on the cover body and configured to provide ions towards the supporting region.

In accordance with some embodiments, a chip transferring method includes at least the following steps. A workpiece is supported by a supporting region of a stage. The supporting region is covered by a cover body located above the supporting region. A chip is picked from the workpiece on the supporting region or the chip is placed to the workpiece on the supporting region, by a pick-and-place component passing through an opening of the cover body.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A chip transferring system, comprising:
a stage, having a supporting region and configured to support a workpiece by the supporting region;
a protection cover, comprising a cover body configured to be located above the supporting region to cover the supporting region, wherein the cover body has an opening; and
a pick-and-place component, configured to pass through the opening of the cover body to pick a chip from the workpiece on the supporting region or place the chip to the workpiece on the supporting region.

2. The chip transferring system of claim 1, wherein the protection cover further comprises at least one ionizer, and the at least one ionizer is disposed on the cover body and configured to provide ions towards the supporting region.

3. The wafer cleaning system of claim 2, wherein the at least one ionizer is a non-fan ionizer.

4. The chip transferring system of claim 1, wherein a width of the opening is greater than a width of the chip.

5. The chip transferring system of claim 1, wherein a width of the cover body is greater than a width of the stage.

6. The chip transferring system of claim 1, wherein the protection cover further comprises at least one movable plate, and the at least one movable plate is disposed on the cover body and configured to move along the cover body to at least partially cover the opening.

7. The chip transferring system of claim 1, wherein the stage is configured to move relatively to the cover body.

8. The chip transferring system of claim 1, wherein the cover body is configured to be placed on the stage.

9. The chip transferring system of claim 8, wherein the protection cover further comprises at least one movable plate, and the at least one movable plate is disposed on the cover body and configured to move along the cover body to formed the opening at different positions on the cover body.

10. The chip transferring system of claim 1, wherein the workpiece is a wafer, a frame or a chip storage box.

11. A protection cover adapted to a chip transferring system, the chip transferring system comprising a stage, the stage having a supporting region for supporting a workpiece, the protection cover comprising:
a cover body, configured to be located above the supporting region to cover the supporting region; and
at least one ionizer, disposed on the cover body and configured to provide ions towards the supporting region.

12. The protection cover of claim 11, wherein the at least one ionizer is a non-fan ionizer.

13. The protection cover of claim 11, further comprising at least one movable plate, wherein the at least one movable plate is disposed on the cover body and configured to move along the cover body to at least partially cover the opening.

14. A chip transferring method, comprising:
supporting a workpiece by a supporting region of a stage;
covering the supporting region by a cover body located above the supporting region; and
picking a chip from the workpiece on the supporting region or placing the chip to the workpiece on the supporting region, by a pick-and-place component passing through an opening of the cover body.

15. The chip transferring method of claim 14, further comprising providing ions towards the supporting region by at least one ionizer.

16. The chip transferring method of claim 15, wherein the at least one ionizer is a non-fan ionizer.

17. The chip transferring method of claim 14, further comprising at least partially covering the opening by at least one movable plate moving along the cover body.

18. The chip transferring method of claim 14, further comprising moving the stage relatively to the cover body.

19. The chip transferring method of claim 14, further comprising placing the cover body on the stage.

20. The chip transferring method of claim 19, further comprising forming the opening at different positions on the cover body by at least one movable plate moving along the cover body.
